(19) United States
(12) Patent Application Publication
(10) Pub. No.: US 2016/0240692 A1
(43) Pub. Date: Aug. 18, 2016

(54) SYSTEMS AND METHODS FOR ASSEMBLING TWO-DIMENSIONAL MATERIALS

(71) Applicant: THE TRUSTEES OF COLUMBIA UNIVERSITY IN THE CITY OF NEW YORK, New York, NY (US)

(72) Inventors: Kenneth L. Shepard, Ossining, NY (US); Inanc Meric, New York, NY (US); Cory R. Dean, New York, NY (US); Lei Wang, New York, NY (US); James Hone, New York, NY (US)

(73) Assignee: THE TRUSTEES OF COLUMBIA UNIVERSITY IN THE CITY OF NEW YORK, New York, NY (US)

(21) Appl. No.: 15/016,933

(22) Filed: Feb. 5, 2016

Related U.S. Application Data
(63) Continuation of application No. PCT/US2014/050580, filed on Aug. 11, 2014.
(60) Provisional application No. 61/864,361, filed on Aug. 9, 2013.

(51) Int. Cl. H01L 29/786; H01L 21/3065; H01L 29/267; H01L 29/16; H01L 29/20; H01L 29/04; H01L 21/02; H01L 21/308

(52) U.S. Cl. CPC H01L 29/78696; H01L 21/02527; H01L 21/0254; H01L 21/02609; H01L 21/0262; H01L 21/3065; H01L 21/308; H01L 29/1606; H01L 29/2003; H01L 29/045; H01L 29/267; H01L 29/78687; H01L 29/78681; H01L 29/78618

(57) ABSTRACT

Heterostructures can include multilevel stacks with an electrical contact on a one-dimensional edge of a two-dimensional active layer. A multilevel stack can be provided having a first two-dimensional layer encapsulated between a second layer and a third layer. A first edge of the first two-dimensional layer can be exposed by etching. A metal can be deposited on the edge of the first two-dimensional layer to form an electrical contact.

### CROSS-REFERENCE TO RELATED APPLICATIONS

This application is a continuation of International Patent Application No. PCT/US2014/050580, filed Aug. 11, 2014, and claims priority to U.S. Provisional Application Ser. No. 61/864,361, filed Aug. 9, 2013, which is incorporated herein by reference in its entirety for all purposes.

### STATEMENT OF FEDERALLY SPONSORED RESEARCH OR DEVELOPMENT

This invention was made with government support from the Air Force Office of Scientific Research under Grant No. MURI/FA9550-09-1-0705, the Office of Naval Research/Defense Advanced Research Projects Agency under Grant No. N000141210814 and the National Science Foundation under Grant No. NEB/DMR-1124894. The government has certain rights in the invention.

### FIELD OF THE INVENTION

The disclosed subject matter relates to systems and methods for assembling two-dimensional materials, including heterostructures.

### BACKGROUND

Atomically thin two-dimensional (2D) materials such as graphene, hexagonal boron nitrides, and the transitional metal dichalogenides (TMDCs) offer certain properties that can be suitable to various applications. One application is assembling multiple 2D materials with complementary properties into layered heterogeneous structures. Encapsulating graphene with BN can yield certain transport properties with reduced environmental sensitivity, and can also provide the capability for complex band structure engineering. Integrating graphene with TMDCs can enable certain tunneling devices and photoactive hybrid materials for flexible electronics. However, several challenges remain.

For example, device engineering can require the ability to make good electrical contact to encapsulating 2D layers. However, electrically interfacing three-dimensional metal electrodes to 2D materials can be problematic. One approach is to metalize the 2D surface. In graphene, the lack of surface bonding sites can inhibit chemical bonding and prevent strong orbital hybridization, resulting in large contact resistance.

In multilayer structures, a need to expose the surface for metalization can present additional challenges. For example, encapsulated BN/graphene/BN heterostructures (BN-G-BN) need to be assembled sequentially to leave the graphene surface accessible during metalization in the absence of a process to selectively remove BN layers. Moreover, polymers are often applied during layer assembly and lithography procedures. Polymers can be difficult to remove and can degrade the electrical contact and channel mobility. The polymers can also contaminate the layer interfaces, potentially resulting in bubbles and wrinkles that can multiply with the addition of each successive layers. This can result in limiting typical device size.

### SUMMARY

The disclosed subject matter provides techniques for assembling two-dimensional materials.

In one aspect of the disclosed subject matter, a method for connecting an electrical contact to a two-dimensional layer along a one-dimensional edge thereof is provided. The method can include providing a multilevel stack including a first two-dimensional layer encapsulated between a second layer and a third layer, exposing an edge of the first two-dimensional layer, and depositing a metal on the edge of the first two-dimensional layer. The first two-dimensional layer can be a graphene layer, and the second and third layers can be hexagonal boron nitride layers.

In accordance with one embodiment of the disclosed subject matter, providing the multilevel stack can include encapsulating the first two-dimensional layer between the second layer and the third layer. For example, encapsulating can include disposing a second material on a polymer layer, stamping a first material onto the second material, and stamping a third material onto the first material. The first material can form the first two-dimensional layer of the multilevel stack. Disposing can include, for example, exfoliating or stamping. The polymer layer can be, for example, a polymer thin film. The method can further include stamping alternating layers of the first material and the third material to add layers to the multilevel stack. For example, the method can include stamping alternating flakes of the first material and flakes of the third material.

In accordance with one embodiment of the disclosed subject matter, stamping the first material onto the second material can include disposing the first material on a substrate and contacting the first material with the second material. Disposing the first material can include exfoliating a flake of the first material onto the substrate or chemical vapor deposition of the first material onto the substrate.

In accordance with embodiments of the disclosed subject matter, exposing the edge of the first two-dimensional layer can include etching such as plasma-etching. A mask can be defined on the second layer prior to etching, and only regions outside of the mask can be etched. The mask can be formed by, for example, electron-beam lithography of a resist.

In accordance with embodiments of the disclosed subject matter, depositing the metal on the edge of the first two-dimensional layer can include electron-beam evaporation or thermal evaporation. The metal can be, for example, chromium, palladium, gold, titanium, nickel, aluminum, or niobium.

In accordance with embodiments of the disclosed subject matter, the heterostructure including the deposited metal can have a contact resistance of less than about 150 Ω·μm, a room-temperature mobility of at least about 140,000 cm²/Vs, and/or a sheet resistivity of less than about 40 Ω/square at n>4×10¹² cm⁻².

In another aspect of the disclosed subject matter, a heterostructure is provided. The heterostructure can be manufactured by a process including providing a multilevel stack including a first two-dimensional layer encapsulated between a second layer and a third layer, exposing an edge of the first two-dimensional layer, and depositing a metal on the edge of the first two-dimensional layer. The first two-dimensional layer can be a graphene layer, and the second and third layers can be hexagonal boron nitride layers.

In accordance with one embodiment of the disclosed subject matter, providing the multilevel stack can include encapsulating the first two-dimensional layer between the second layer and the third layer. For example, encapsulating can include disposing a second material on a polymer layer, stamping a first material onto the second material, and stamping a third material onto the first material. The first material can form the first two-dimensional layer of the multilevel stack. Disposing can include, for example, exfoliating or stamping. The polymer layer can be, for example, a polymer thin film. The method can further include stamping alternating layers of the first material and the third material to add layers to the multilevel stack. For example, the method can include stamping alternating flakes of the first material and flakes of the third material.

In accordance with one embodiment of the disclosed subject matter, stamping the first material onto the second material can include disposing the first material on a substrate and contacting the first material with the second material. Disposing the first material can include exfoliating a flake of the first material onto the substrate or chemical vapor deposition of the first material onto the substrate.

In accordance with embodiments of the disclosed subject matter, exposing the edge of the first two-dimensional layer can include etching such as plasma-etching. A mask can be defined on the second layer prior to etching, and only regions outside of the mask can be etched. The mask can be formed by, for example, electron-beam lithography of a resist.

In accordance with embodiments of the disclosed subject matter, depositing the metal on the edge of the first two-dimensional layer can include electron-beam evaporation or thermal evaporation. The metal can be, for example, chromium, palladium, gold, titanium, nickel, aluminum, or niobium.

In accordance with embodiments of the disclosed subject matter, the heterostructure can have a contact resistance of less than about 150 Ω·μm, a room-temperature mobility of at least about 140,000 cm²/Vs, and/or a sheet resistivity of less than about 40 Ω/square at n>4×10¹² cm⁻².

In accordance with another aspect of the disclosed subject matter, a heterostructure is provided. The heterostructure can include a first two-dimensional layer including an electrical contact disposed on a one-dimensional edge thereof, a second layer, and a third layer. The first two-dimensional layer can be disposed between the second layer and the third layer. The first two-dimensional layer can be a graphene layer, and the second and third layers can be hexagonal boron nitride layers. The electrical contact can be formed from a metal including, for example, chromium, palladium, gold, titanium, nickel, aluminum, or niobium.

In accordance with embodiments of the disclosed subject matter, the heterostructure can have a contact resistance of less than about 150 Ω·μm, a room-temperature mobility of at least about 140,000 cm²/Vs, and/or a sheet resistivity of less than about 40 Ω/square at n>4×10¹² cm⁻².

It is to be understood that both the foregoing general description and the following detailed description are exemplary and are intended to provide further explanation of the disclosed subject matter claimed.

The accompanying drawings, which are incorporated in and constitute part of this specification, are included to illustrate and provide a further understanding of the disclosed subject matter. Together with the description, the drawings serve to explain the principles of the disclosed subject matter.

### BRIEF DESCRIPTION OF THE DRAWINGS

FIG. 1 is a flow chart of an exemplary method for connecting an electrical contact to a two-dimensional layer along a one-dimensional edge thereof in accordance with the disclosed subject matter.

FIG. 2 is a schematic diagram of a multilevel stack in accordance with an exemplary embodiment of the disclosed subject matter.

FIG. 3 is a flow diagram of an exemplary method for encapsulating a first two-dimensional layer between a second layer and a third layer in accordance with the disclosed subject matter.

FIG. 4 is a schematic diagram of an exemplary method for encapsulating a first two-dimensional layer between a second layer and a third layer in accordance with the disclosed subject matter.

FIG. 5A is a flow diagram of an exemplary method for exposing an edge in accordance with the disclosed subject matter.

FIG. 5B is a schematic diagram of a mask defined on the multilevel stack in accordance with an exemplary embodiment of the disclosed subject matter.

FIG. 6 is a schematic diagram of a heterostructure in accordance with an exemplary embodiment of the disclosed subject matter.

FIG. 7A is a STEM image showing details of the edge contact geometry of an exemplary embodiment of a heterostructure in accordance with the disclosed subject matter.

FIG. 7B shows EELS mapping of individual elements at a metal-graphene contact region of an exemplary embodiment of a heterostructure in accordance with the disclosed subject matter.

FIG. 8 is a graph showing two terminal resistance versus channel length at fixed density, measured from a single graphene device in accordance with an exemplary embodiment of the disclosed subject matter. Solid lines show linear fit to the data. The inset shows an optical image of a TLM device with edge contacts.

FIG. 9 is a graph showing contact resistance calculated from the linear fit at multiple densities for two separate devices in accordance with exemplary embodiments of the disclosed subject matter. Error bars represent uncertainty in the fitting. Inset shows resistance scaling with contact width measured from another device in accordance with an exemplary embodiment of the disclosed subject matter.

FIG. 10 is a graph showing measured contact resistance R_{C} as a function of carrier density. A comparison between R_{C} extracted by the TLM (left) and R_{C} extracted by the Landauer Buttiker model excluding the quantum resistance (right) is shown.

FIG. 11 is a graph showing measured contact resistance as a function of temperature from 8K to 400K for an exemplary embodiment of a device in accordance with the disclosed subject matter.

FIG. 12A is a schematic structure of a modeled Cr—O-graphene interface in accordance with an exemplary embodiment of the disclosed subject matter.

FIG. 12B is a graph showing calculated transmission as a function of energy for different metal-graphene contact structures in accordance with embodiments of the disclosed subject matter.

FIG. 12C is a graph showing calculated interfacial contact resistance as a function of energy from the transmission in FIG. 12B.

FIG. 13A-FIG. 13C are graphs showing metal-graphene edge contact resistance as a function of carrier density of three devices in accordance with the disclosed subject matter. The device of FIG. 13A has metal contacts deposited after lithography defining the leads without O₂ plasma. The device of FIG. 13B has a graphene edge that was exposed to 15 s O₂ plasma before metal deposition. The device of FIG. 13C has a graphene edge that was exposed to 25 s metal plasma before metal deposition.

FIG. 14A is an optical image showing in sequence a BN flake on PPC film picking up the top graphene flake, the middle BN flake, and the bottom graphene flake in accordance with an exemplary embodiment of the disclosed subject matter.

FIG. 14B is an optical image showing the steps for making a BN—MoS₂—BN stack in accordance with an exemplary embodiment of the disclosed subject matter.

FIG. 15 is an atomic force microscope image showing an area of an encapsulated graphene layer of a stack fabricated in accordance with an exemplary embodiment of the disclosed subject matter.

FIG. 16A and FIG. 16B show STEM images of the device of FIG. 15. FIG. 16A is a high resolution cross section ADF-STEM image of the device shown in FIG. 15. FIG. 16B is a raw STEM image taken with shorter acquisition times.

FIG. 17 is a graph of four-terminal resistivity measured from a 15 μm×15 μm device fabricated in accordance with an exemplary embodiment of the disclosed subject matter. Inset left shows an optical image of the device.

FIG. 18A is a diagram of a device in accordance with an exemplary embodiment of the disclosed subject matter in van der Pauw geometry used to characterize sheet resistivity.

FIG. 18B is a graph of measured resistances as a function of gate voltage for an exemplary device in accordance with the disclosed subject matter. The two curvers show the resistances for the two configurations in van der Pauw geometry: Rₐ and R_{b}.

FIG. 19 is a graph showing room temperature mobility versus density of a device in accordance with an exemplary embodiment of the disclosed subject matter. The dashed black curve indicates theoretical mobility limit due to acoustic-phonon scattering. The remaining data points label the range of mobilities reported in the literature for high performance 2D semiconductor FETs.

FIG. 20A is a graph showing calculated means free path density for the device shown in FIG. 17.

FIG. 20B is a graph showing temperature for the device shown in FIG. 17. The shaded region in FIG. 20B indicates the temperature below which the mean free path exceeds the device size. Circles and squares correspond to the “a” configuration and triangles correspond to the “b” configuration of the van der Pauw measurements.

FIG. 21 is a graph of the lower bound mean free path at T=1.7 K for devices with size varying from 1 μm to 5 μm in accordance with exemplary embodiments of the disclosed subject matter.

FIG. 22 is a graph showing a comparison of the resistivity and conductivity of a device produced according to an exemplary embodiment of the vdW transfer technique in accordance with the disclosed subject matter. before and after thermal anneal.

FIG. 23 is a graph of the resistivity as a function of back gate voltage of a BN-G-BN device in accordance with an exemplary embodiment of the disclosed subject matter, before and after exposing the device to O₂ plasma.

Throughout the drawings, the same reference numerals and characters, unless otherwise stated, are used to denote like features, elements, components or portions of the illustrated embodiments. Moreover, while the disclosed subject matter will now be described in detail with reference to the Figs., it is done so in connection with the illustrative embodiments.

### DETAILED DESCRIPTION

The disclosed subject matter provides techniques for assembling heterostructures including one or more two-dimensional layers. More specifically, the disclosed subject matter provides for assembling heterostructures including at least one two-dimensional layer with an electrical contact.

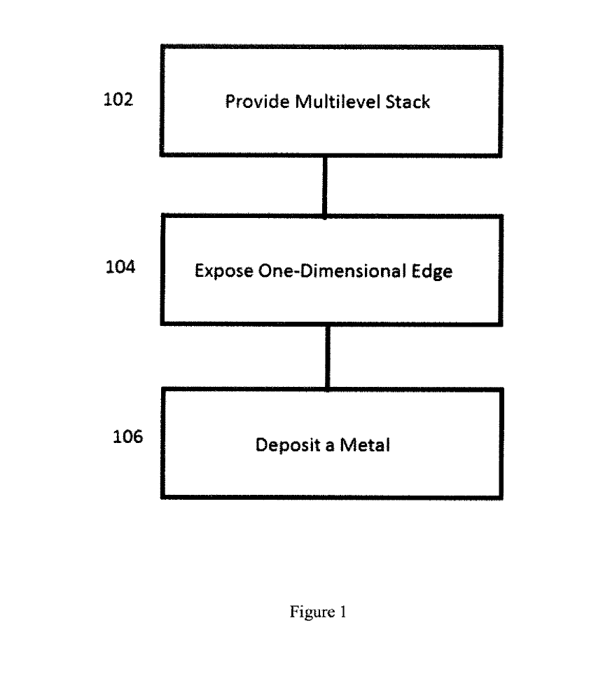

In one aspect, the presently disclosed subject matter provides a method for connecting an electrical contact to a two-dimensional layer along a one-dimensional edge thereof. An exemplary embodiment of the method for connecting an electrical contact to a two-dimensional layer along a one-dimensional edge thereof is illustrated in FIG. 1. A multilevel stack can be provided (at 102).

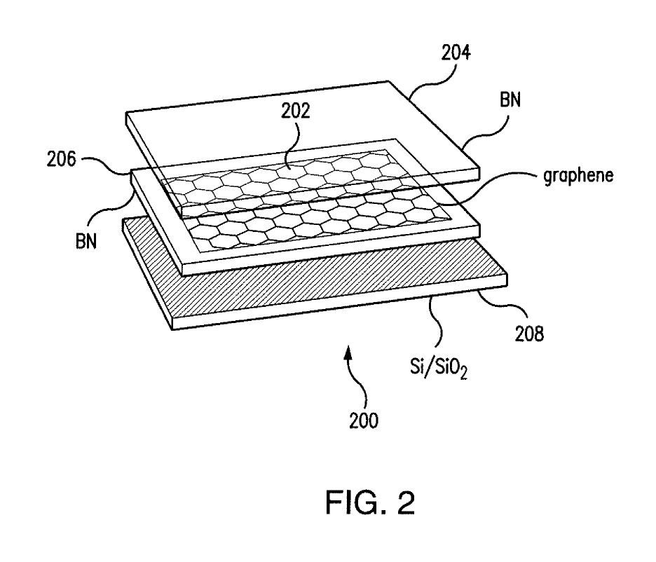

A multilevel stack in accordance with one embodiment of the disclosed subject matter is illustrated in FIG. 2. The multilevel stack 200 includes a first two-dimensional layer 202 encapsulated between a second layer 204 and a third layer 206. The second layer 204 and third layer 206 can be insulating layers, The multilevel stack 200 is shown with three layers, but can also include more than three layers. For example, multilevel stacks in accordance with other embodiments of the disclosed subject matter can include five, seven, or nine layers of two-dimensional layers.

In accordance with one embodiment of the disclosed subject matter, the first two-dimensional layer 202 can be a monolayer. The first two-dimensional layer 202 can be constructed from graphene. However, in accordance with other embodiments of the disclosed subject matter, the first two-dimensional layer 202 can be construed from other suitable materials including, for example and without limitation, hexagonal boron nitride, transition metal dichalcogenides, molybdenum disulfide, germanane, silicene, and silicon carbide.

The second and third layers can be two-dimensional layers or layers of finite thickness. In accordance with an embodiment of the disclosed subject matter, the second layer 204 and the third layer 206 can be formed from the same material. For example, both the second layer 204 and the third layer 206 can be construed from hexagonal boron nitride. However, in other embodiments, one or both of second layer 204 and the third layer 206 can be constructed from other suitable materials including, for example and without limitation, graphene, transition metal dichalcogenides, molybdenum disulfide, germanane, silicene, silicon carbide, and amorphous oxides such as SiO₂. In accordance with the certain embodiments, the second layer 204 and the third layer 206 can be monolayers or can be formed by two or more two-dimensional layers of the same material.

The multilevel structure 200 can be provided on a substrate 208. The substrate can be constructed from any suitable material including, for example, silicon or silicon dioxide.

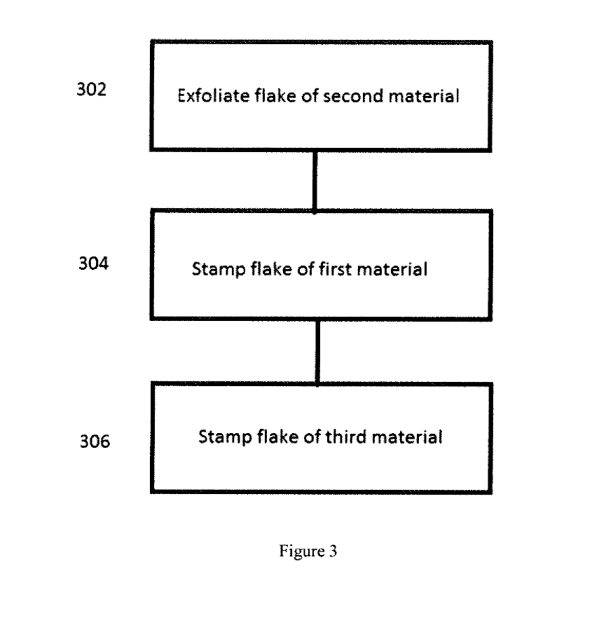

In accordance with embodiments of the disclosed subject matter, providing the multilevel structure can include fabricating the multilevel structure. FIG. 3 illustrates a method for encapsulating a first two-dimensional layer between a second layer and a third layer in accordance with an exemplary embodiment of the disclosed subject matter.

The material forming the second layer can be disposed onto a layer of polymer. The layer of polymer can be, for example, a polymer thin film (PTF) such as poly-propylene carbonate or poly(methyl methacrylate) (at 302). In accordance with one embodiment, the one or more flakes of the material forming the second layer (which will hereafter be referred to as the “second material”) can be exfoliated onto the polymer thin film. For example, a substrate such as a silicon chip can be coated with polymer film poly-propylene carbonate (PPC). In accordance with one embodiment, about 1 μm of PCC can be coated on the substrate. Flakes of the “second material can then be exfoliated onto the surface of the PPC. The second material can be, for example, hexagonal boron nitride. In accordance with embodiments of the disclosed subject matter, the flakes can be examined (e.g., by optical microscopy and/or atomic force microscopy) to identify an atomically smooth flake. The PPC can be peeled from the substrate and placed on a stamp. The stamp can be, for example, an elastomer stamp such as a poly dimethyl siloxane (PDMS) stamp. The PPC is placed on the stamp with the side having the second material facing outwards. The stamp can then be affixed to a microscope slide.

In accordance with other embodiments of the disclosed subject matter, techniques other than exfoliation can be used to dispose the second material onto the polymer layer. For example, in accordance with one embodiment of the disclosed subject matter, the polymer layer can be disposed on the stamp by, e.g., direct spinning of the polymer layer onto the stamp or spinning the polymer layer onto a substrate and then transferring the polymer layer to the stamp. The second material can then be stamped with the stamp to dispose the second material onto the polymer layer, as described below.

The material forming the first two-dimensional layer (hereafter the “first material”) can then be stamped with the stamp (at 304). For example, one or more flakes of the first material (e.g., graphene) can be exfoliated or otherwise disposed onto a wafer such as a silicon wafer or a silicon oxide wafer. In accordance with another embodiment of the disclosed subject matter, the first material can be disposed onto a substrate using chemical vapor deposition. The flakes can be examined by optical microscopy and atomic force microscopy. The slide with the PDMS stamp can be attached to a micromanipulator such that the flake of the second material is on the bottom. The manipulator positions the flake of the second material over the flake of the first material and the two flakes are brought into contact. The manipulator then lifts the stack. The flake of the first material adheres more strongly to the flake of the second material than to the substrate, and is thus lifted from the substrate. Without wishing to be bound by any particular theory, it is believed that this adhesion results from strong van der Waals (vdW) interaction between the two-dimensional materials. This process can be performed at a stage temperature of about 40° C.

The material forming the third layer (hereafter the “third material”) can then be stamped (at 306). For example, the process described above with respect to the first material can be repeated. In accordance with one embodiment of the disclosed subject matter, the process can be further repeated to create stacks with an arbitrary number of layers.

After the multilevel stack has been fabricated, the stack can be placed on a substrate. The substrate can then be heated (for example, to 90° C.) to soften the PPC. The glass slide and PDMS can be removed. The PPC can then be removed in chloroform to leave the multilevel stack on the substrate.

In accordance with embodiments of the fabrication process, the first two-dimensional layer is never exposed to any polymers or solvents. Such a process can reduce the impurities trapped between the layers.

The method for encapsulating a first two-dimensional layer between a second layer and a third layer illustrated in FIG. 3 can be performed using a variety of materials. For example, the first two-dimensional layer can be, for example, graphene. The second and third materials can be, for example, hexagonal boron nitride.

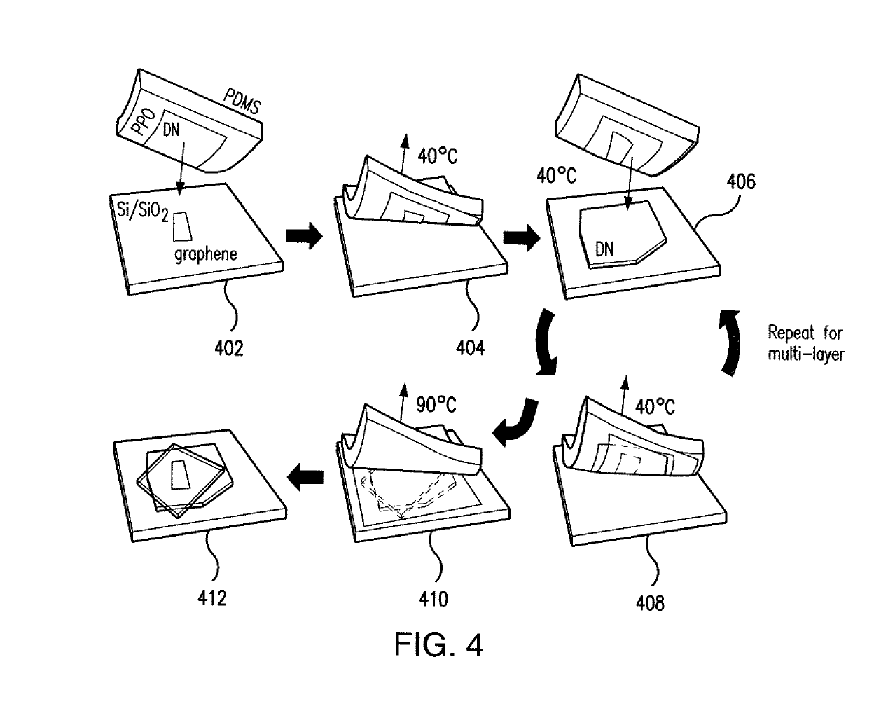

The stamping method in accordance with one embodiment of the disclosed subject matter is illustrated in FIG. 4. First, a flake of the first material can be stamped (at 402). The stamp can then be removed from the substrate, and the flake of the first material will adhere to the flake of the second material (at 404). A flake of the third material is then stamped (at 406). The stamp can then be removed from the substrate, and the flake of the third material will adhere to the flake of the first material (at 408). The substrate can then be heated to soften the PPC and permit the removal of the glass slide and PDMS stamp (at 410). Finally, the PPC can be removed and the multilevel structure remains on the substrate (at 412).

With further reference to FIG. 1, an edge of the first two-dimensional layer can be exposed (at 104). The edge can be exposed using an etching technique such as plasma-etching.

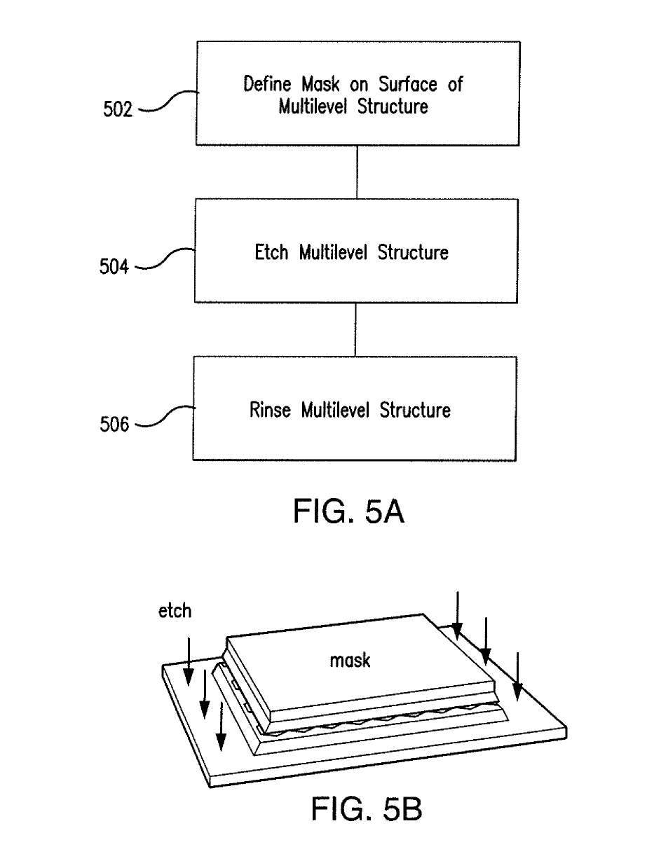

An etching process that can be used in accordance with the disclosed subject matter is illustrated in FIG. 5A. A mask can be defined on the second layer (at 502). For example, a PMMA layer can be etched onto the second layer. The PMMA layer can be etched in an oxygen plasma. The PMMA layer can have a thickness of about 70 nm. Electron beam lithography can then be used to pattern a hydrogen silsesquioxane (HSQ) layer on the PMMA layer. In accordance with another embodiment of the disclosed subject matter, the HSQ layer can be etched directly on the second layer.

The multilevel stack can then be etched (at 504). As illustrated in FIG. 5B, the mask protects the multilevel stack such that only regions of the multilevel stack outside the mask are etched. The stack can be etched using plasma etching. For example, the stack can be etched in an Oxford ICP 80 system using plasma generated from a mixture of O₂ and CHF₃ gases. The flow rates of the O₂ and CHF₃ gases can be about four standard cubic centimeters per minute (sccm) and 40 sccm, respectively. The etch rate of hexagonal boron nitride, which can be used as the second and/or third material in accordance with an exemplary embodiment of the disclosed subject matter, has an etch rate of approximately 30 nm/min under 60 W RF power.

Finally, the multilevel stack can be rinsed (at 506). For example, in accordance with one embodiment of the disclosed subject matter, the multilevel stack can be rinsed with acetone to remove the mask. In another embodiment, the mask can be removed using a suitable acid such as hydrofluoric acid. In accordance with certain embodiments, the mask can remain on the second layer and no rinsing is required.

With further reference to FIG. 1, a metal can be deposited to form an electrical contact (e.g., metal leads) (at 106). The metal can be deposited using, e.g., electron beam evaporation or thermal evaporation. In accordance with one embodiment of the disclosed subject matter, the metal can be chromium. In accordance with another embodiment, the metal can include chromium in combination with one or more other metals. Other metals that can be used in accordance with the disclosed subject matter, either alone or in combination with one or more additional metals, can include but are not limited to palladium, gold, titanium, nickel, aluminum, and niobium, as well as metal alloys such as gold-palladium and niobium nitride.

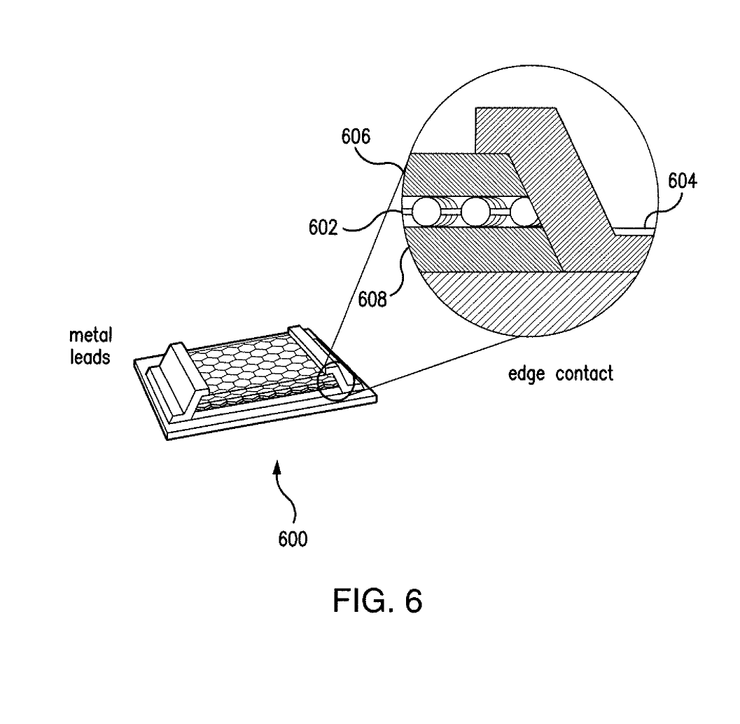

In another aspect, the presently disclosed subject matter provides a heterostructure. An exemplary embodiment of a heterostructure in accordance with the disclosed subject matter is illustrated in FIG. 6. The heterostructure 600 includes a first two dimensional layer 602 comprising an electrical contact 604 disposed on a one-dimensional edge thereof. The electrical contact 604 can be disposed on the edge of the two-dimensional layer 602 in accordance with the methods disclosed herein. The first two-dimensional layer 602 can be constructed from any suitable material including, for example and without limitation, graphene, hexagonal boron nitride, transition metal dichalcogenides, molybdenum disulfide, germanane, silicene, and silicon carbide. The electrical contact 604 can be constructed of one or more metals including chromium, palladium, gold, titanium, nickel, and aluminum.

The heterostructure 600 further includes a second layer 606 and a third layer 608. The first two-dimensional layer 602 can be encapsulated between the second layer 606 and the third layer 608. In accordance with an embodiment of the disclosed subject matter, the second layer 606 and the third layer 608 can be formed from the same material. For example, both the second layer 606 and the third layer 608 can be construed from a suitable material such as hexagonal boron nitride, graphene, transition metal dichalcogenides, molybdenum disulfide, germanane, silicene, or silicon carbide.

The heterostructure 600 in accordance with the disclosed subject matter can have a low contact resistance. For example, in accordance with embodiments of the disclosed subject matter, the contact resistance between the electrical contact and the first two-dimensional layer can be less than about 200 Ω·μm, less than about 150 Ω·μm, or less than about 100 Ω·μm. For example, the contact resistance can be about 200 Ω·μm, about 180 Ω·μm, about 160 Ω·μm, about 140 Ω·μm, about 120 Ω·μm, or about 100 Ω·μm.

The heterostructure 600 in accordance with the disclosed subject matter can also have high room-temperature mobility and low sheet resistivity. For example, the room-temperature mobility for graphene can be more than about 120,000 cm²/Vs, more than about 130,000 cm²/Vs, or more than about 140,000 cm²/Vs. For example, the room-temperature mobility can be about 125,000 cm²/Vs, about 130,000 cm²/Vs, about 135,000 cm²/Vs, or about 140,000 cm²/Vs. The sheet resistivity can be below about 60 Ω/square, below about 50 Ω/square, or below about 40 Ω/square at n>4×10¹² cm⁻². For example, the sheet resistivity can be about 55 Ω/square, about 50 Ω/square, about 45 Ω/square, or about 40 Ω/square.

Heterostructures in accordance with the disclosed subject matter can exhibit ballistic behavior over length scales larger than 15 μm at temperatures below 40 K.

### Example 1

### Metalization

In this Example, a hard mask is defined on the top BN surface of a BN-G-BN heterostructure using electron beam lithography. More particularly, electron beam lithography was used to pattern to HSQ layer to define the device shape. The PMMA layer was then etched in an oxygen plasma. The BN-G-BN stack is then etched in an Oxford ICP system using plasma generated from a mixture of O₂ and CHF₃ gases with a flow rate of four standard subic centimeters (sccm) and 40 sccm respectively. The etch rate of BN is about 30 nm/min under 60 W RF power. The sample was then rinsed with acetone to remove the PMMA and HSQ mask. Metal leads (1 nm Cr/15 nm Pd/60 nm Au) were deposited by electron beam evaporation making electrical contact along the edge.

Scanning transmission electron microscope (STEM) images were prepared using device cross sections. Device cross sections for STEM were fabricated using standard focused ion beam lift-out procedures in a dual-beam FEI Strata 400 focused ion beam (FIB) system. Before cross-sectioning, samples were coated with a ˜˜10-40 nm layer of amorphous carbon followed by a thick Pt layer to protected exposed layers. Samples were backed for >10 hours at 130° C. in ultra-high vacuum before loading into the microscope. For STEM imaging, a NION ultra-STEM100 equipped with a Gatan Enfinium spectrometer for electron energy-loss spectroscopy (EELS) was used. A convergence angle of 25 mrad was used. The scope was operated at 100 kV, with care taken to limit the dose, and no damages was observed in the graphene or BN layers. ADF-STEM images were acquired with a medium-angle annular detector. EELS spectrum imaging was used to identify different elements and distinguish between graphene and BN layers. The EELS edges were processed and quantified in part by using the open-source Cornell Spectrum Imager software. To correct for sample drift and other distortions, STEM images were cross-correlated perpendicular to the scan direction. To do so, the image was acquired with the scan perpendicular to the basal plane of the layers. Then, the image as processed by taking each scan line, fitting a Gaussian to the position of the graphene layer, and aligning the center of the Gaussian in each layer.

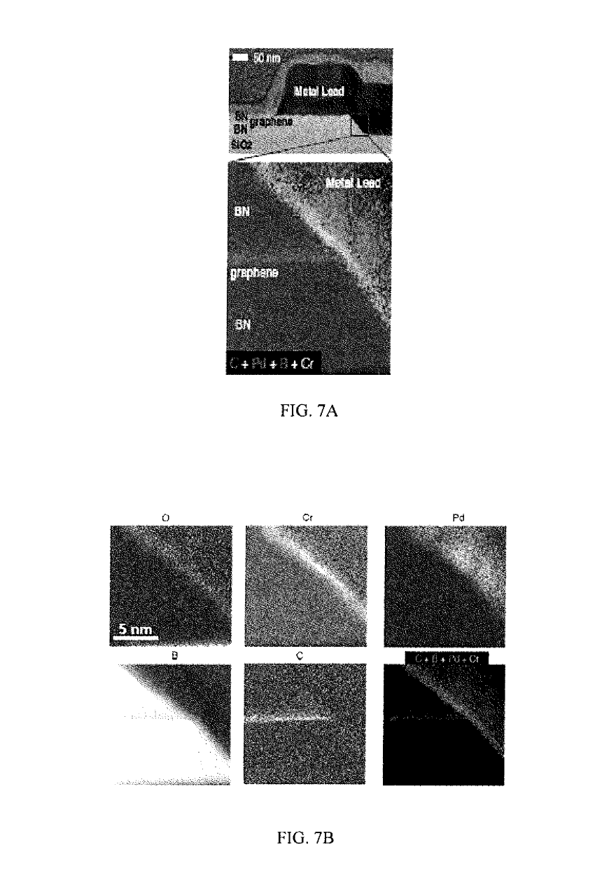

A cross-section STEM image of a representative device (FIG. 7A) shows the resulting geometry of the edge contact. In the magnified region, electron-energy-loss-spectroscopy (EELS) mapping confirms that the graphene and metal overlap at a well-defined interface. From the angle of the etch (approximately 30°) it is expected that the graphene terrace exposed only 1-2 atoms deep and within the resolution of the STEM image. There is no evidence of metal diffusion into the graphene/BN interface, confirming the truly edge nature of the contact. The EELS map additionally indicates that contact is made predominantly to the Cr adhesion layer

EELS composition maps were extracted from a 128×128 pixel spectrum image (30 ms per pixels). Individual maps (FIG. 7B) were produced by applying a power-law background subtraction, then integrating under the B—K, O—K, Cr-L_{2,3} and Pd-M_{4,5} edges respectively. Data was acquired in a NION Ultra-STEM 100.

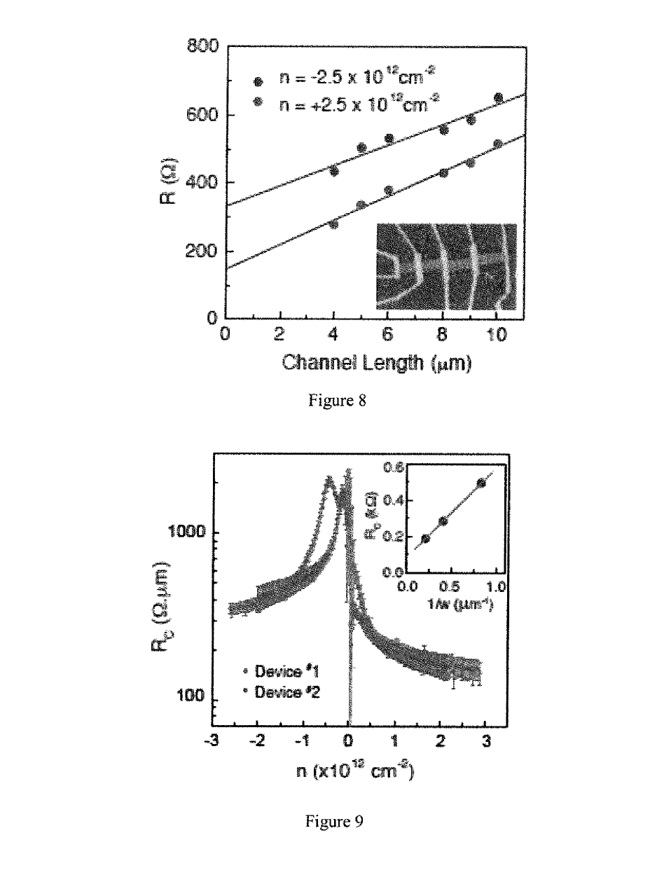

To characterize the quality of the edge contact, the transfer length method (TLM) was used. Multiple two-terminal graphene devices consisting of a uniform 2 μm channel width but with varying channel lengths were fabricated, and their resistances were measured as a function of carrier density n induced by a voltage applied to a silicon back gate. Resistance versus channel length measured at two different carrier densities is shown in FIG. 8. In the diffusive regime, where the channel length remains several times longer than the mean free path, the total resistance in a two-terminal measurement can be written as R=2R_{C}(W)+ρL/W, where R_{C} is the contact resistance, L is the device length, W is the device width, and p is the 2D channel resistivity. R_{C} and ρ are extracted as the intercept and slope of a linear fit to the data.

The contact resistance versus carrier density measured for two separate devices is shown in FIG. 9. R_{C} is remarkably low, reaching approximately 150 Ω·μm for n-type carriers at high density. As a comparison, this value is approximately 25% lower than the best reported surface contacts without additional engineering such as chemical or electrostatic doping. This value is obtained in a two-terminal geometry, so it includes the intrinsic limit set by the quantum resistance of the channel, which can be subtracted to yield an extrinsic contact resistance close to 100 Ω·μm. In both devices the contact resistance is asymmetric, being lower by a factor of about of 2-3 when the device is gated to be n-type versus p-type. This asymmetry is consistent with electrical contact being made primarily to the Cr adhesion layer, as suggested by the cross-section EELS map shown in FIG. 7A, because the Cr work function is approximately 0.16 eV lower than that of graphene. The contact resistance scales inversely with the contact width as shown in FIG. 9, as expected for the edge-contact geometry.

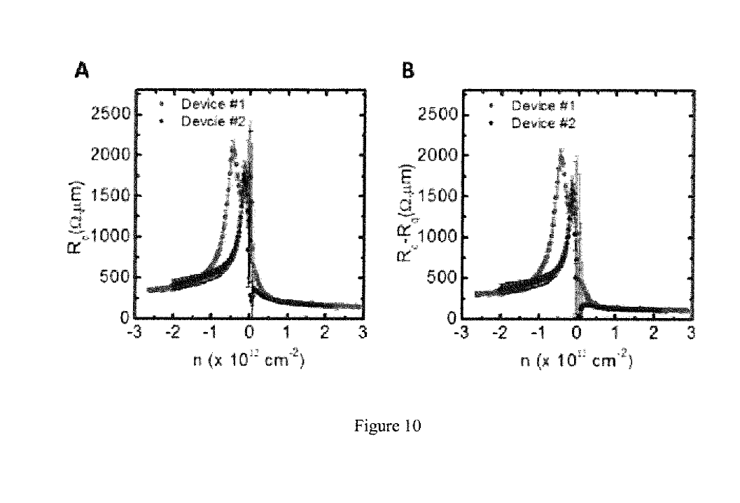

From the Landauer-Buttiker model, the finite number of conducting channels in the graphene leads to a quantum resistance, R_{q}, that contributes to R_{C}. This can be calculated from R_{q}=(1/w)(h4e²)sqrt(n/n), assuming uncorrelated channels. FIG. 10 shows a comparison between the measured contact resistance and the extrinsic contact resistance (R_{C}−R_{q}) that arises only from the finite transmission probability at the barrier. The resistance of devices 1 and 2 are plotted as a function of channel length for every charge density value n, where n is calculated from n=C_{g} (V_{g}−V₀)/e. As shown in FIG. 10, (R_{C}−R_{q}) is nearly independent of carrier density on the electron side. On the hole side, there is a peak at low carrier density, which is different from the Dirac peak of the channel at zero density.

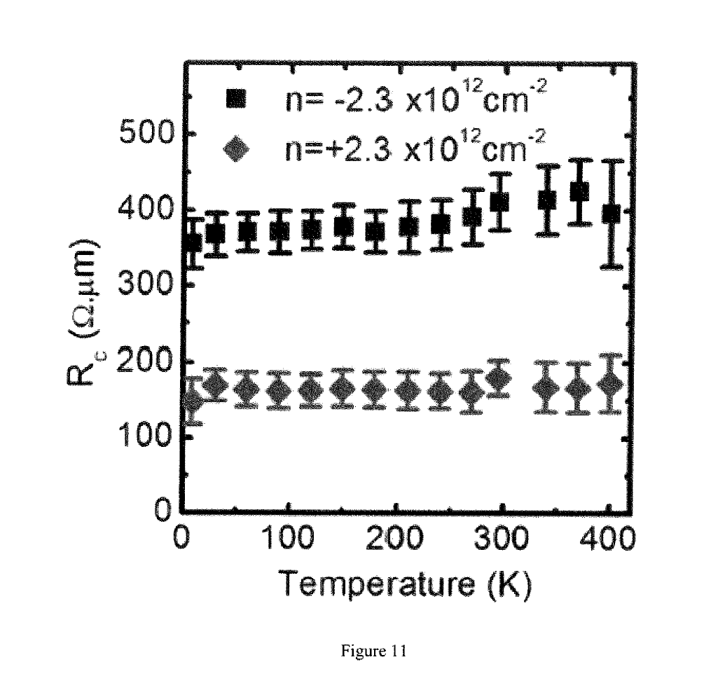

Finally, the contact resistance is largely independent of temperature. FIG. 11 shows the measured contact resistance as a function of temperature from 8K to 400K at a carrier density of −2.3×10¹² cm⁻² and +2.3×10¹² cm⁻². Contact resistance for both electrons and holes at a high density are shown. In contrast, linear temperature-scaling has been reported for surface contacts.

Ab initio density functional theory calculations and DFT-NEGF transport calculations using the ATK package were performed to understand why edge contacts can lead to low contact resistance. The exchange-correlation interaction between electrons is described with the local density approximation (LDA) scheme. Two different metal (Cr) surface orientations of [100] and [110] were simulated for graphene edge contacts. The super cell of interfacial atomistic structure consists of a slab of six layers of metal atoms and a graphene sheet with its edge attached to the most symmetrical point of the metal surface, which is the most stable configuration. The atomistic structure was relaxed until the maximum force is smaller than 0.05 eV/Angstrom. After relaxation, ab initio NEGF simulation is performed to calculate the transmission for the interface. For ab initio NEGF transmission calculation, the k-point mesh density was chosen to be 1000 in the transverse direction of graphene, which is proven dense enough by performing a convergence test. The distance between the interfacial atoms and the first atomistic layer of the Cr contact of the relaxed edge structures are shown in Table 1. For comparison, the distance between the graphene sheet and the first metal surface for surface contact is 2.01 Å for Cr[100] and 1.94 Å for Cr [110]. The edge contacts lead to shorter bonding distances that can contribute to larger orbital overlap compared to the surface contacts, due to different natures of the bond mechanism.

TABLE 1

| | | | Cr100-O- |
|---|---|---|---|
| | Cr110-graphene | Cr110-O-graphene | graphene |
| Distance between | 1.42 | 1.44 | 1.26 |
| Cr surface and | | | |
| interfacial atom (Å) | | | |

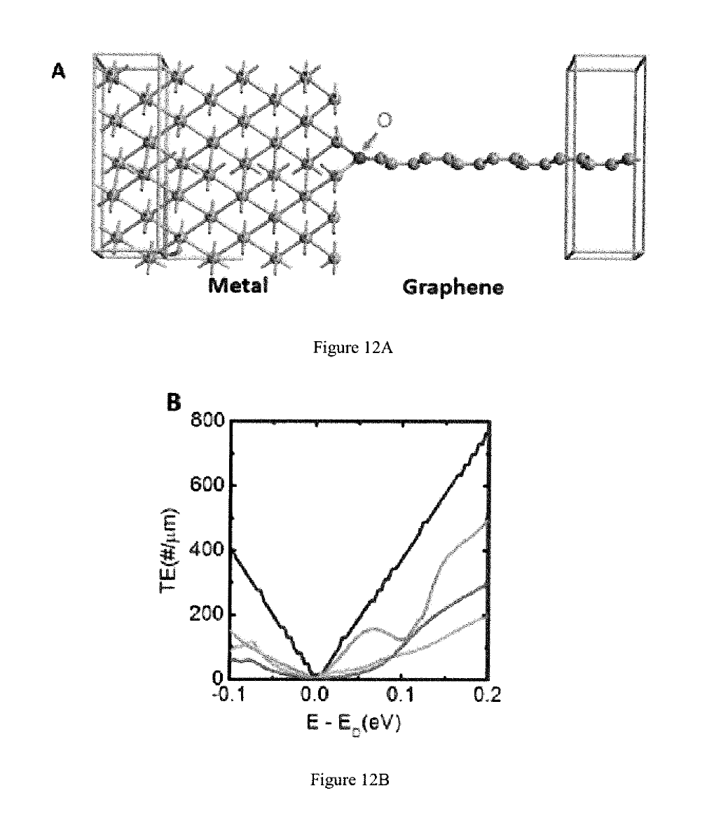

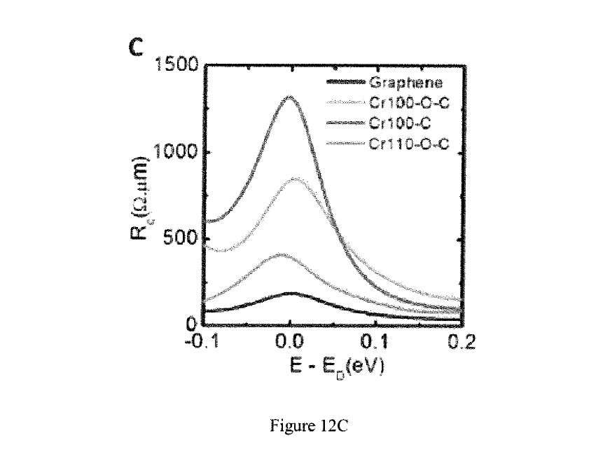

Carrier transport properties cross the contact interface were simulated using ab initio NEGF approach as shown in FIG. 12A. FIG. 12B compares the transmission as a function of energy of different edge contact structures to a perfect graphene monolayer. The results indicate that interfacial carrier transport can be highly efficient in spite of the atomic thickness of the contact. Incorporation of interfacial species such a 0, which passivates the graphene edge before formation of metal contacts, could help to increase transmission.

The total contact resistance includes both the interfacial resistance and a contribution from transport in the band bending region near the metal contacts in graphene. As the Cr work function is slightly lower than graphene by about 0.16 eV, the contact resistance at high n-type density is mostly limited by the interface. The interface contact resistance was further computed from the transmission as shown in FIG. 12B by using the Landauer formula, as shown in FIG. 12C. For Cr110-O-graphene structure at E−E_{dirac}=0.16 eV, which corresponds to the graphene-Cr workfunction difference and a n-type density of 2.2×10¹² cm⁻², an interface resistance of about 118 Ω·μm is calculated. Variation of the interface structure leads to somewhat different modeled resistance at the same energy, but the results are qualitatively similar for all structures.

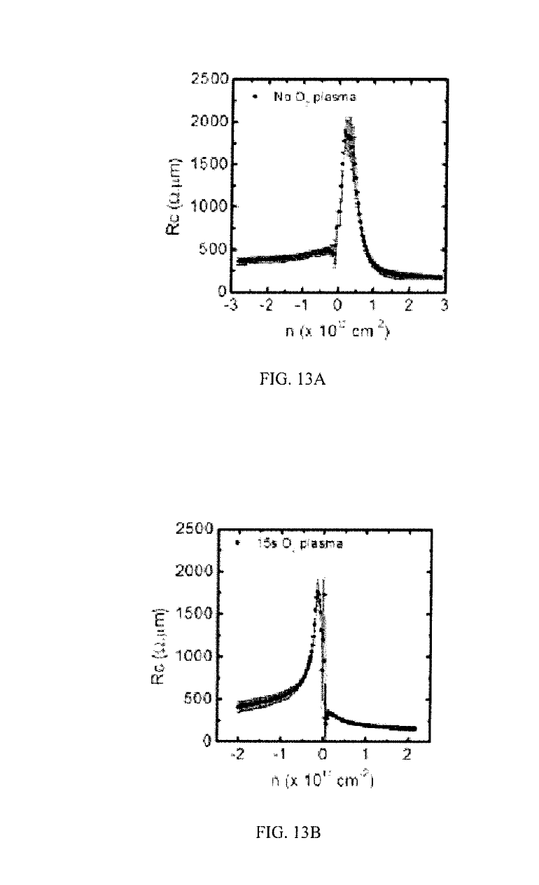

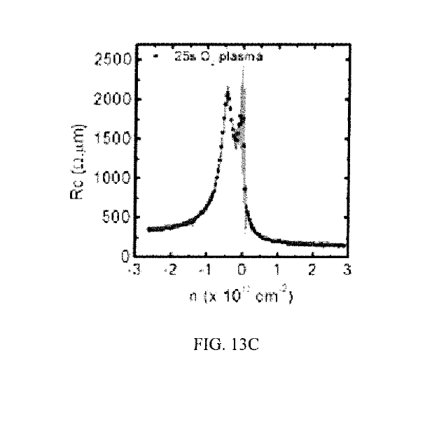

In both the data and the model the contact resistance diverges near the charge neutrality point. This can be expected owing to a decrease of density of states in the 2D graphene layer. FIG. 13A through FIG. 13C illustrate metal-graphene edge contact resistance as a function of carrier density of three devices. The plasma used to etch BN-G-BN stacks contains C, F, O, and H radicals. In conjunction with the resist residue from lithography defining the leads, many types of chemical termination of the exposed edges can be selected. The etched BN-G-BN was therefore exposed to a gentle O₂ plasma before metal evaporation, with the intention of modifying the graphene edge. As shown in FIG. 13A through FIG. 13C, the resistance at high carrier density (>10¹² cm⁻²) is negligibly affected by the O₂ plasma treatment for both electrons and holes. At low carrier density, a peak in R_{C} was observed which does not correspond to the charge neutrality peak (CNP). The position of this peal shifts with O₂ plasma exposure, indicating that it is related to the graphene termination chemistry.

The use of different metal combinations for the metal leads was also investigated. Metal-graphene edge contacts using different metal thicknesses and combinations were fabricated as shown in Table 2. The same geometry was used for all devices. For all metals, deposition was carried out under a vacuum of 10⁻⁷ Torr. Nickel, palladium, gold, and titanium were evaporated at a rate of 0.5 Å/s using an electron beam system. Aluminum was evaporated at the same rate using a thermal system. Metal-graphene edge contacts with a chromium layer (either electron beam or evaporated) were found to be especially suitable.

TABLE 2

| | | Number of | Contact resistance at | |
|---|---|---|---|---|
| Metal Type | Layer Thickness | Samples | n = 10¹² cm⁻² | |
| Cr/Pd/Au | 1 nm/15 nm/50 nm | 5 | 140~180 | Ω · μm |
| Cr/Au | 10 nm/50 nm | 3 | 160~200 | Ω · μm |
| Ti/Au | 15 nm/50 nm | 2 | ~10 | kΩ · μm |
| Pd/Au | 15 nm/50 nm | 2 | ~100 | kΩ · μm |
| Au | 50 nm | 2 | Open | |
| Ni/Au | 15 nm/50 nm | 2 | ≧10 | MΩ · μm |
| Al/Au | 15 nm/50 nm | 2 | ~100 | kΩ · μm |

Contact resistance for metals such as the metals identified in Table 2 can be improved by optimizing evaporation techniques.

### Example 2

### Fabrication of Multilevel Stack

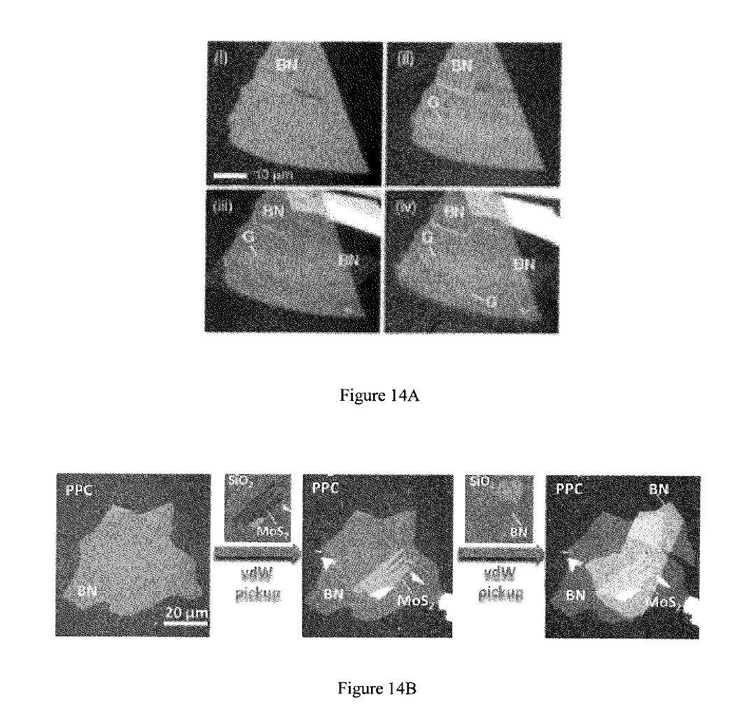

A multilevel stack was formed using an isolated few-layer BN flake to successively pick up alternating layers of monolayer graphene and few-layer BN. Strong van der Waals (vdW) interaction between 2D materials was used to directly assemble the layered structure. A bare Si chip was coated with approximately 1 μm of poly-propylene carbonate (PPC) (Sigma-Aldrich, CAS 25511-85-7). BN flakes were exfoliated onto the surface of the PPC and examined by optical microscopy and atomic force microscopy to find an atomically smooth flake with thickness between approximately 10 nm and 30 nm. The PPC was then manually pulled from the Si substrate and placed on a transparent elastomer stamp (poly dimethyl siloxane, or PDMS), BN side-up. The stamp is then inverted and affixed to a microscope slide. In parallel, flakes of graphene and BN were exfoliated onto Si/SiO₂ (285 nm) wafers and examined by optical microscopy and atomic force microscopy. To make a BN-G-BN stack, the slide with the PDMS stamp was inverted and attached to a micromanipulator, such that the BN flake was on the bottom. The manipulator was used to position the BN flake over a chosen graphene flake, bring the two flakes into contact, and the lift the stack. The graphene adheres more strongly to the BN than to the SiO₂ and is lifted from the substrate. It was found that setting the stage temperature to 40° C. produced the best results (nearly 100% yield). The process was then repeated to pick up the bottom BN flake. The stack was then placed on the desired substrate and heated to 90° C. to soften the PPC which allowed the glass slide and PDMS to be removed. The PPC was removed in chloroform to leave the BN-G-BN on the substrate. FIG. 14A shows optical images of this process. Although this technique is described with reference to graphene, other two-dimensional materials can also be used. For example, FIG. 14B shows optical images showing the use of this process to form a BN—MoS₂—BN stack.

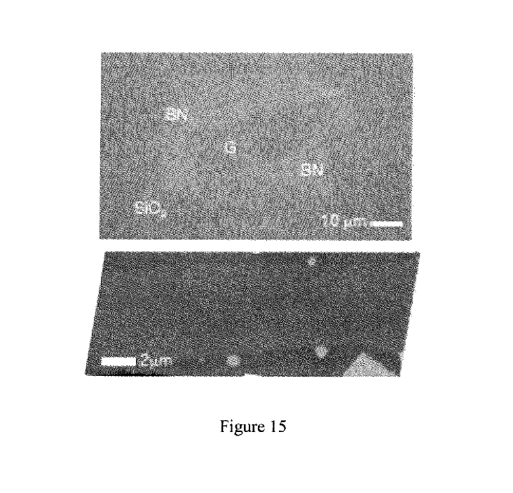

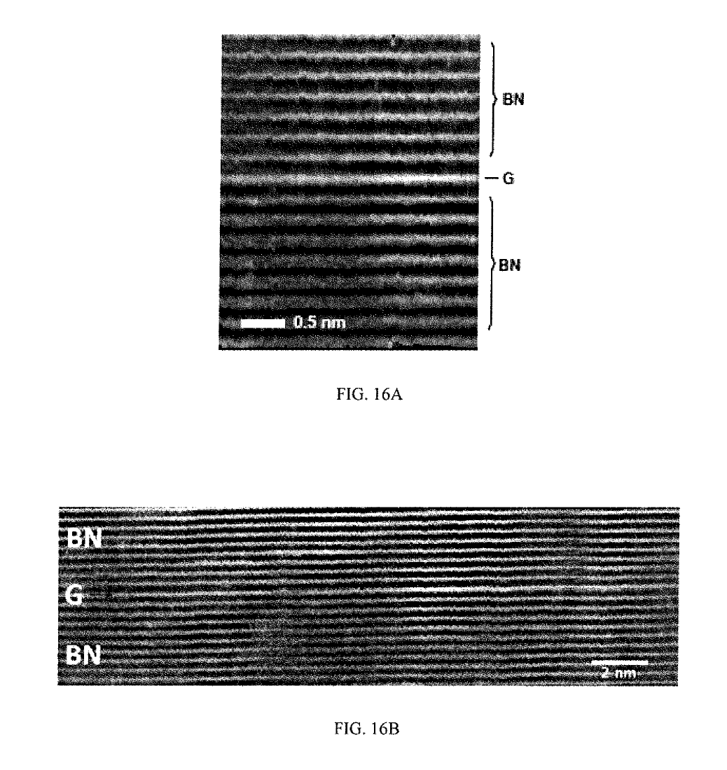

The active interfaces did not contact any polymer throughout the process, reducing impurities trapped between the layers. FIG. 15 shows an atomic force microscope image of a BN-G-BN heterostructure made by vdW assembly. The graphene appears clean and free of macroscopic contamination over the entire device area of approximately 200 μm². FIG. 16A shows a high resolution cross section STEM image indicating that the resulting interface layer is pristine down to the atomic scale, with the graphene layer nearly indistinguishable from the adjacent BN lattice planes. A raw image, taken with shorter acquisition times, is shown in FIG. 16B and confirms that the sharpness and cleanliness of the G/BN interfaces is independent of image processing.

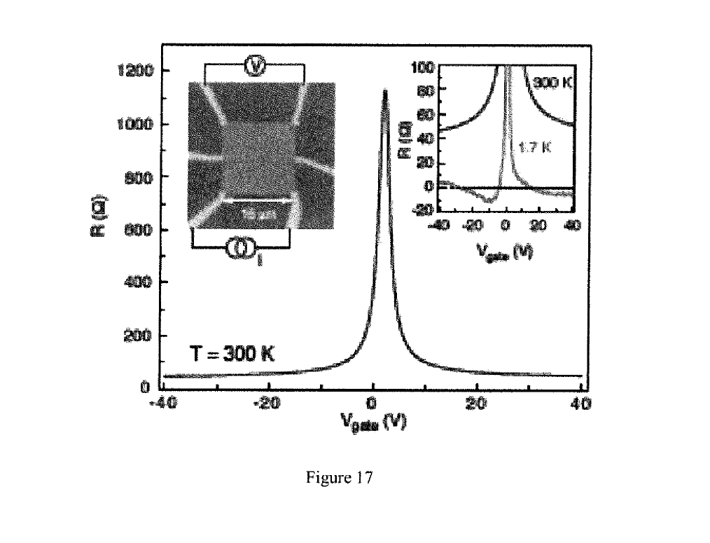

FIG. 17 shows electrical transport from a large area, 15 μm×15 μm, BN-G-BN device fabricated by combining vdW assembly with edge contacts. The transport characteristics indicate the graphene device to be remarkably pristine, reaching a room temperature mobility in excess of 140,000 cm²/Vs.

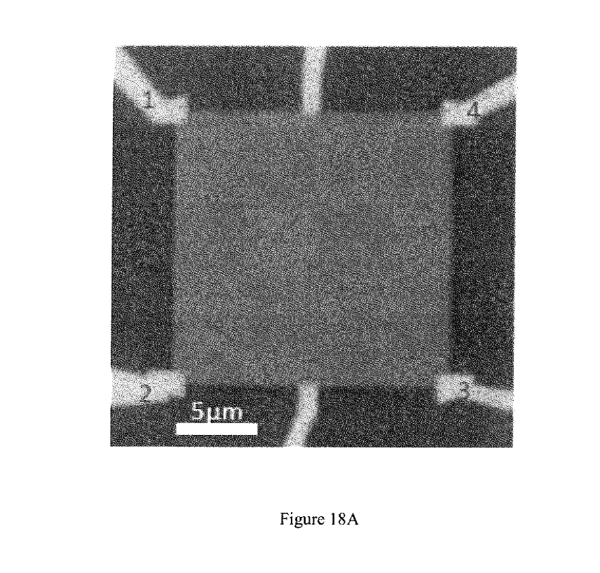

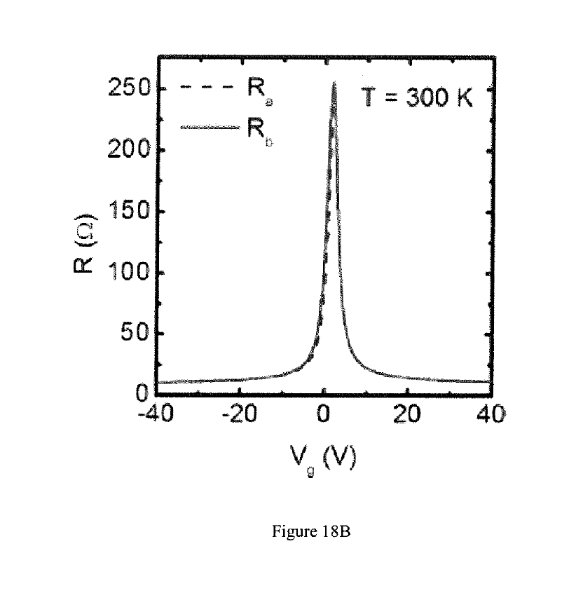

Calculation of sheet resistivity is explained with reference to FIG. 18A, which shows a device with contacts 1, 2, 3, and 4 along the periphery. The resistance Rₐ (configuration “a”) is defined as Rₐ=V₃₄/I₁₂ where I₁₂ flowing from contact 1 to contact 2 is sourced by a lockin amplifier output at a frequency of 17 Hz. V₃₄=V₃−V₄ is the voltage difference between the contacts 3 and 4, measured by the same lockin amplifier. R_{b} (configuration “b”) is defined similarly. Assuming the contacts are negligibly small (contact width is only about 6% of the side length of the device), the sheet resistivity is calculated by ρ=(π/ln [2])F([Rₐ+R_{b}]/2) where F is a function of the ratio Rᵣ=Rₐ/R_{b}, satisfying the relation (Rᵣ−1)/(Rᵣ+1)=(F/ln [2])arcosh(exp[ln(2)/F]/2). As shown in FIG. 18B, due to the highly symmetric device structure, the measured resistances at room temperate as a function of gate voltage for R_{A} and R_{b} have nearly identical values so F can be found to be ≈1, and the sheet resistivity can be approximated by 4.53×Rₐ. In the low temperature ballistic regime, four-terminal measurement is dominated by mesoscopic effects and van der Pauw geometry becomes unreliable.

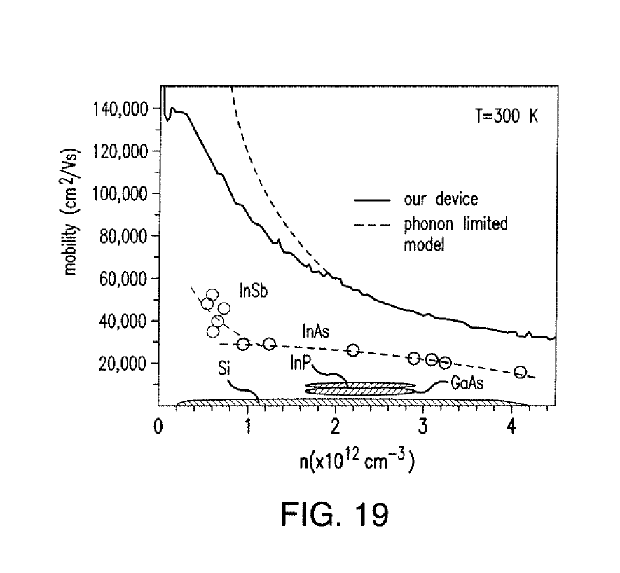

At carrier density |n|=4.5×10¹² cm⁻², the sheet resistivity is less than 40 Ω/square, corresponding to an equivalent 3D resistivity of only 1.5 μΩ·cm, smaller than the resistivity of any metal at room temperature. Thus, the device simultaneously realizes both high mobility and large carrier density. Using the simple Drude model of conductivity, σ=neμ, where μ is electron mobility, a mobility of approximately 40,000 cm²/Vs is calculated at densities as large as n˜4.5×10¹² cm⁻². In this high-density regime the measured mobility is comparable to the acoustic-phonon-limited mobility theoretically predicted for intrinsic graphene. The room temperature response of this graphene device outperforms all other 2D materials, including the highest mobility 2D heterostructures fabricated from III-V semiconductors (FIG. 19) by at least a factor of two over the entire range of technologically relevant carrier densities.

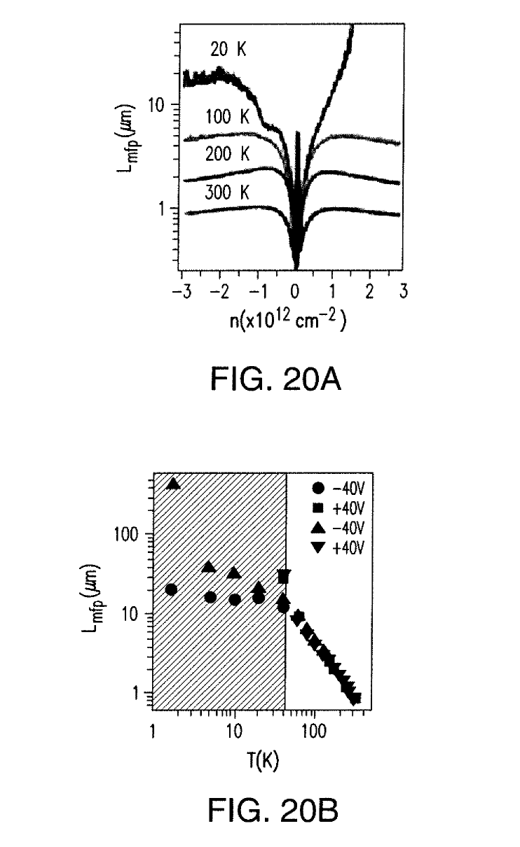

At low temperatures, four-terminal measurement yields a negative resistance (as shown in FIG. 17), indicating quasi-ballistic transport over at least 15 μm. In the diffusive regime, the mean free path, L_{mfp}, can be calculated from the conductivity, a, according to L_{mfp}=σh/2e²k_{F} where k_{F}=sqrt(πn) is the Fermi wave factor. In FIG. 20A, L_{mfp} versus applied gate voltage is shown for selected temperatures from 300 K down to 20 K. The mean free path increases with gate voltage until it saturates to a temperature-dependent value at a high density. This maximum L_{mfp} increases monotonically with decreasing temperature until the mean free path approaches the device size at T˜40K (as shown in FIG. 20B). In the low-temperature ballistic regime, four-terminal measurement is dominated by mesoscopic effects and the calculated mean free path exhibits large variation, depending on the measurement geometry. The temperature dependence therefore provides only a lower bound of the mean free path. The negative resistance observed at base temperature indicates that electrons travel ballistically across the diagonal of the square, corresponding to a mean free path as large as 21 μm in this device. This corresponds to an electron mobility of approximately 1,000,000 cm²/Vs at a carrier density of ˜3×10¹² cm⁻².

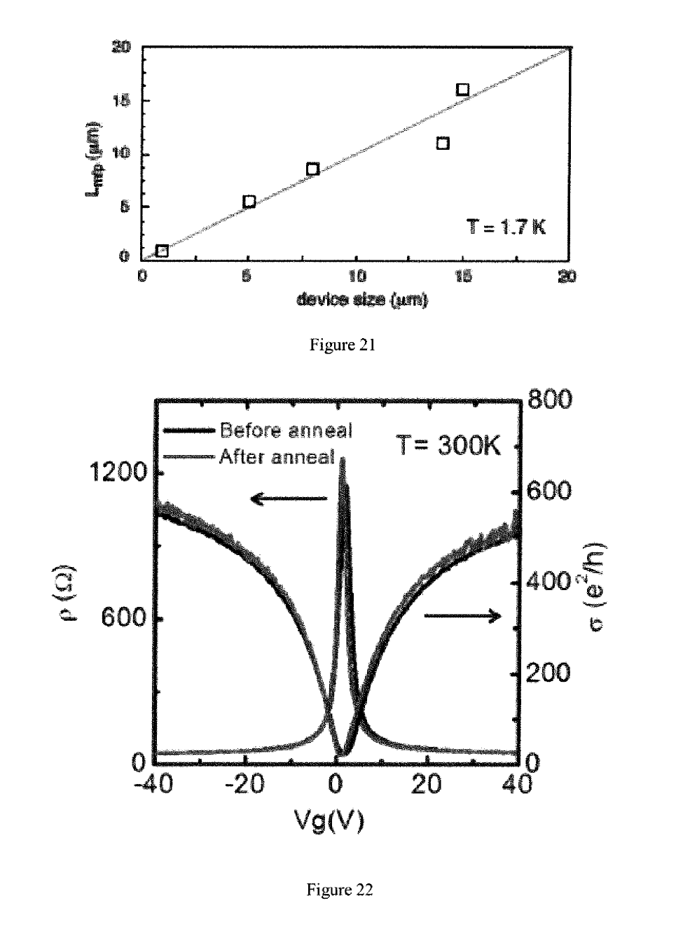

The measurements were repeated for devices varying in size from 1 to 15 μm. As seen in FIG. 21, the maximum mean free path scales linearly with device size. This result indicates that in the devices the low temperature mobility is limited by the available crystal size and the intrinsic impurity-limited scattering length has not been reached. Even higher mobility can be expected for larger-area devices, which can be enabled by recent progress in scalable growth techniques.

In a previous assembly technique, the graphene flake was directly affixed to a polymer (such as PPC or poly methyl methacrylate (PMMA) by annealing at ˜400° in an Ar/H₂ atmosphere. To determine whether a similar process is required for a vdW transfer technique, room-temperature performance was measured before and after annealing. FIG. 22 shows the resistivity as a function of gate voltage before and after thermal annealing. In contrast to the large changes seen in samples produced by polymer transfer, the device resistance at high carrier density changed less than 2% after annealing. Importantly, eliminating the need for annealing greatly eases integration with substrates (such as CMOS wafers or flexible polymers) that can be damaged by excessive heating. In samples produced by polymer transfer, the presence of residual polymer residue, even after annealing, leads to interfacial “bubbles” when a second BN layer is placed on top of the graphene. These bubbles limit device size to only ˜1 μm and ake assembly of more complex structures containing many active layers extremely difficult. The vdW transfer technique eliminates interfacial contamination and minimizes interfacial bubbles, such that device size is limited only by the available crystal size and multi-layer stacks can be easily created simply by repeated “pick-up.”

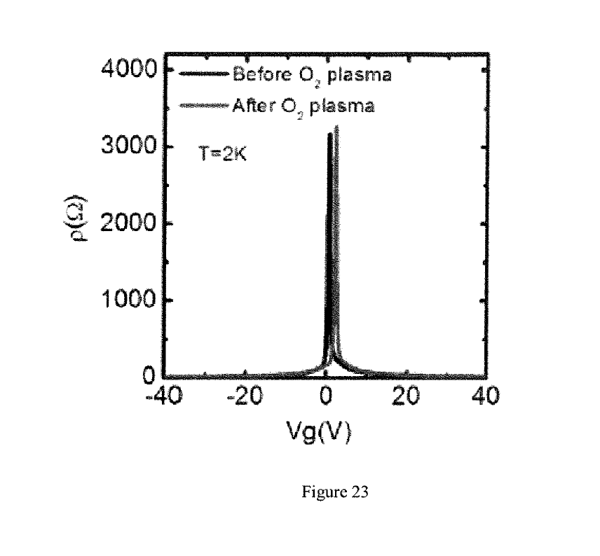

As shown in FIG. 22, thermal cycling has a negligible effect on the transport properties. To further investigate the environmental sensitivity, the devices were exposed to a very reactive O₂ plasma. A sample with top BN thickness of ˜20 nm was exposed to an O₂ plasma with 50 W power for 20 seconds. The resistivity as a function of function of gate voltages at base temperature before and after plasma treatment is shown in FIG. 23. The only change in device performance is a small shift of ˜2 V in the position of the Dirac peak.

The presently disclosed subject matter is not to be limited in scope by the specific embodiments herein. Indeed, various modifications of the disclosed subject matter in addition to those described herein will become apparent to those skilled in the art from the foregoing description and the accompanying figures. Such modifications are intended to fall within the scope of the appended claims.

1. A method for connecting an electrical contact to a two-dimensional layer along a one-dimensional edge thereof comprising:
providing a multilevel stack comprising a first two-dimensional layer encapsulated between a second layer and a third layer;
exposing an edge of the first two-dimensional layer; and
depositing a metal on the edge of the first two-dimensional layer.

2. The method of claim 1, wherein the first two-dimensional layer comprises graphene.

3. The method of claim 1, wherein the second layer and the third layer comprise hexagonal boron nitride.

4. The method of claim 1, wherein the providing comprises encapsulating the first two-dimensional layer between the second layer and the third layer.

5. The method of claim 4, wherein the encapsulating comprises:
disposing a material forming the second layer onto a polymer layer;
stamping a material forming the first two-dimensional layer onto the material forming the second layer; and
stamping a material forming the third layer onto the material forming the first two-dimensional layer.

6. The method of claim 5, wherein the disposing comprises exfoliating.

7. The method of claim 5, wherein the disposing comprises stamping.

8. The method of claim 5, wherein the polymer layer comprises a polymer thin film.

9. The method of claim 5, wherein stamping the material forming the first layer comprises:
disposing the material forming the first layer onto a substrate; and
contacting the material forming the first layer with the material forming the second layer.

10. The method of claim 9, wherein the disposing the material forming the first layer onto a substrate comprises exfoliating a flake of the material forming the first layer onto the substrate.

11. The method of claim 9, wherein the disposing the material forming the first layer onto a substrate comprises chemical vapor deposition.

12. The method of claim 5, further comprising stamping alternating flakes of the material forming the first two-dimensional layer and flakes of the material forming the third layer to add additional layers to the multilevel stack.

13. The method of claim 1, wherein the exposing the edge of the first two-dimensional layer comprises etching.

14. The method of claim 13, wherein the etching comprises plasma-etching.

15. The method of claim 13, further comprising:
defining a mask on the second layer prior to etching; and
etching regions of the multilevel stack outside of the mask.

16. The method of claim 15, wherein the defining the mask comprises electron-beam lithography of a resist.

17. The method of claim 1, wherein the depositing comprises electron-beam evaporation.

18. The method of claim 1, wherein the depositing comprises thermal evaporation.

19. The method of claim 1, wherein the metal comprises chromium.

20. The method of claim 1, wherein the metal comprises at least one metal selected from a group consisting of palladium, gold, titanium, nickel, aluminum, and niobium.

21. The method of claim 1, wherein the heterostructure comprising the deposited metal has a contact resistance of less than about 150 Ω·μm.

22. The method of claim 1, wherein the heterostructure comprising the deposited metal has a room-temperature mobility of at least about 140,000 cm²/Vs.

23. The method of claim 1, wherein the heterostructure comprising the deposited metal has a sheet resistivity of less than about 40 Ω/square at n>4×10¹² cm⁻².

24. A heterostructure manufactured by a process comprising:
providing a multilevel stack comprising a first two-dimensional layer encapsulated between a second layer and a third layer;
exposing an edge of the first two-dimensional layer; and
depositing a metal on the edge of the first two-dimensional layer.

25. The heterostructure of claim 24, wherein the first two-dimensional layer comprises graphene.

26. The heterostructure of claim 24, wherein the second layer and the third layer comprise hexagonal boron nitride.

27. The heterostructure of claim 24, wherein the providing comprises encapsulating the first two-dimensional layer between the second layer and the third layer.

28. The heterostructure of claim 27, wherein the encapsulating comprises:
disposing a material forming the second layer onto a polymer layer;
stamping a material forming the first two-dimensional layer onto the material forming the second layer; and
stamping a material forming the third layer onto the material forming the first two-dimensional layer.

29. The heterostructure of claim 28, further comprising stamping alternating flakes of the material forming the first two-dimensional layer and flakes of the material forming the third layer to add additional layers to the multilevel stack.

30. The heterostructure of claim 24, wherein the exposing the edge of the first two-dimensional layer comprises etching.

31. The heterostructure of claim 30, wherein the etching comprises plasma-etching.

32. The heterostructure of claim 30, further comprising:
defining a mask on the second layer prior to etching; and
etching regions of the multilevel stack outside of the mask.

33. The heterostructure of claim 32, wherein defining the mask comprises electron-beam lithography of a resist.

34. The heterostructure of claim 24, wherein the depositing comprises electron-beam evaporation.

35. The heterostructure of claim 24, wherein the metal comprises chromium.

36. The heterostructure of claim 24, wherein the heterostructure has a contact resistance of less than about 150 Ω·μm.

37. The heterostructure of claim 24, wherein the heterostructure has a room-temperature mobility of at least about 140,000 cm²/Vs.

38. The heterostructure of claim 24, wherein the heterostructure has a sheet resistivity of less than about 40 Ω/square at n>4×10¹² cm⁻².

39. A heterostructure comprising:
a first two-dimensional layer comprising an electrical contact disposed on a one-dimensional edge thereof;
a second layer; and
a third layer,
wherein the first two-dimensional layer is disposed between the second layer and the third layer.

40. The heterostructure of claim 39, wherein the first two-dimensional layer comprises graphene.

41. The heterostructure of claim 39, wherein the second layer and the third layer comprise hexagonal boron nitride.

42. The heterostructure of claim 39, wherein the electrical contact comprises chromium.

43. The heterostructure of claim 39, wherein the heterostructure has a contact resistance of less than about 150 Ω·μm.

44. The heterostructure of claim 39, wherein the heterostructure has a room-temperature mobility of at least about 140,000 cm²/Vs.

45. The heterostructure of claim 39, wherein the heterostructure has a sheet resistivity of less than about 40 Ω/square at n>4×10¹² cm⁻².
